(19) United States
(12) Patent Application Publication
(10) Pub. No.: US 2005/0211157 A1
(43) Pub. Date: Sep. 29, 2005

(54) Process control system for controlling a crystal-growing apparatus

(76) Inventors: Olexy V. Radkevich, Schaumburg, IL (US); Keith Ritter, Addison, IL (US); Yuriy Yakovlev, Palatine, IL (US)

Correspondence Address: Elsa Keller;Siemens Corporation, Intellectual Property Department, 170 Wood Avenue South, Iselin, NJ, 08830, US

(21) Appl. No.: 10/809,623

(22) Filed: Mar. 25, 2004

(51) Int. Cl. C30B 1/00; C30B 3/00; C30B 5/00; C30B 28/02; C30B 15/00; C30B 21/06; C30B 27/02; C30B 28/10; C30B 30/04

(52) U.S. Cl. 117/10

(57) ABSTRACT

A process control system for a crystal-growing apparatus is provided which includes a process controller and a temperature controller. The temperature controller includes an input terminal which receives a temperature adjustment signal from a bottom heat thermocouple indicating the melt temperature. Based on the melt temperature, the temperature controller determines whether to increase, decrease or keep constant the melt temperature. The temperature controller further includes two additional input terminals which receive pulses from a pulse generator of the process controller for automatically controlling temperature switches of a bottom heater temperature controller in accordance with the sensed level of the melt. The pulses are generated by the pulse generator upon receiving data with respect to how much the temperature needs to be adjusted and in which direction (increase or decrease).

### BACKGROUND OF THE INVENTION

1. Field of the Invention

The present invention relates to an apparatus for growing single crystals by pulling the single crystals from a melt on a seed. More particularly, the present invention relates to a process control system for controlling a crystal-growing apparatus.

2. Description of the Related Art

Various types of crystals, e.g., sodium chloride, potassium chloride, potassium bromide, lithium fluoride, sodium iodide, cesium iodide, germanium, silicon, lead tellurides, etc., used for optics and semi-conductors are typically grown from a melt or raw material which forms on a seed under controlled chemical conditions.

The Czochralski technique for growing crystals is one technique which originates from the pioneering work of Jan Czochralski who in 1917 first managed to successfully pull single crystals of various metals. Since then the Czochralski technique has been used to grow germanium and silicon and has been extended to grow a wide range of compound semiconductors, oxides, metals, and halides. It is considered the dominant technique for the commercial production of most of these materials. Generally, the process involves the vertical pulling of a seed crystal when contacted with the surface of a molten reservoir of the raw material which is then gradually pulled upwardly with rotation to form the single crystal.

More particularly, the Czochralski technique typically involves the following steps:
filling a suitable crucible with the raw material, e.g., Silicone (Si);
dissolving the raw material in the crucible and keeping its temperature close to the melting point.
inserting a seed crystal while rotating the crucible and adjusting the temperature to start withdrawing the seed crystal (during the first or initial pull, the diameter of the growing crystal will decrease to a few millimeters which is known as the “dash process” which ensures that the crystal will be dislocation free even though the seed crystal may contain some dislocations);
adjusting the growth rate to grow the commercial part of the crystal at a few mm/second at a desired diameter;
Adjusting the temperature, pull rate and rotational speed to maintain the homogeneity of the crystal until the melt is almost exhausted; and
Increasing the pull rate to reduce the diameter of the crystal and establish an “end cone” which signifies the end of homogeneous crystal growth.

It is important to note that as the crystal grows the impurity concentration of the melt increases which results in a higher percentage of impurities in the crystal. Moreover, as the amount of the impurities increases, the temperature profile will also change, i.e., the crystal tends to cool more slowly as you grow deeper into the crucible. In addition and depending upon the type of material being grown, other parameters may have to be controlled to yield a desired result.

It is known that obtaining single crystals with pre-selected properties and perfect crystalline structure is dependent on a host of complicated parameters, such as providing stability and axial symmetry of the temperature field in the growing single crystal and the melt surrounding it; maintaining the present solid-liquid interface shape; providing adequate agitation of the melt to wash over the solid-liquid interface; and providing a stable growth rate at the predetermined diameter of the growing single crystal.

Other issues may also arise during crystal growth of a particular material. For example, some compounds may require a very high pressure which must be maintained around the growing crystal area to control the vaporization of a volatile component such as arsenic or phosphorus. In other crystal growing processes, it may be necessary to supply a moderate to high vacuum. Typically, the working zone within the crystal growing apparatus includes some sort of relief valve to permit control of the zone atmosphere, whether it is pressurized or evacuated during crystal growth.

One particular known apparatus for pulling single crystals from melt on a seed by the Czochralski method includes a sealed chamber with water-cooled walls and a crucible disposed therein such that the vertical axis of the crucible is aligned with the vertical axis of the chamber. The crucible is enclosed within a heater encompassed by a thermal insulator. The upper portion of the chamber accommodates a vertical rod having an axis which is aligned with that of the crucible axis. The rod is sealingly received through the top or lid of the chamber and is axially reciprocable. The lower end of the rod carries the seed holder, while its upper end is associated with a rotator which rotates and axially reciprocates the rod.

The initial material is melted in the crucible and the rotating rod with the seed is lowered into the crucible until the seed comes into contact with the melt. The melt temperature is somewhat lowered to discontinue the melting of the seed and thereafter the rod with the seed is slowly pulled while rotated to grow a single crystal on the seed. The diameter is predetermined by correspondingly adjusting the melt temperature and/or the pull rate.

The crystal pulling is performed discontinuously over definite time intervals. With reference to FIG. 1, by rapidly lifting crystal holder 1 at a certain distance ΔL, which is short enough that, as a result of partial extraction of a convex crystallization front from the melt, the area of the contact surface between the growing crystal and the melt changes insignificantly, it is possible to use probe 2 of the level sensor to measure the corresponding value of ΔH; that is, the melt level drop in crucible 3.

From geometric considerations, the following relationship between crystal diameter d, crucible diameter D, and values of L and H can be easily obtained: d=D(ΔH/(ΔH+ΔL))^{1/2}. Accordingly, by measuring the value of ΔH using the probe 2, the crystal diameter d can be determined using this relationship. The measured value of d is then compared using a comparator (see FIG. 2) with a preset or predetermined diameter value and according to the discrepancy between the values, temperature correction is performed by controlling the amount of heat generated by a bottom heater 4 via a temperature controller as described below with reference to FIG. 2.

Thereafter, in order to restore the melt column to its initial height level, raw material is fed to the melt. The raw material is fed via tube 5 to peripheral annular channel 6 of the crucible 3. The raw material melts within the annular channel 6 by side heater 7 and flows down to the melt through holes 8. The level sensor follows the rise in height of the melt column and controls the shut-off of the feed supply at a predetermined time before the appropriate melt level is obtained. After a short interval, the melt level stabilizes and the cycle is subsequently repeated.

Thus, the melt level sensor performs two functions: measures the diameter of the growing crystal and controls the mean feeding rate of the raw material. With this set-up, unlike the case where the raw material is continuously being fed, there is no need to stabilize the rate that the raw material is fed to the annular channel 6. It is sufficient only to maintain not too low a feeding rate which would waste time for the restoration of the initial melt level and not too high a feeding rate which after shutting-off the feed allows the melt level to stabilize too quickly. By maintaining a suitable feeding rate, there is provided a better opportunity to precisely measure the growing crystal diameter using the above relationship. Nonetheless, the above-described crystal growing process is a complicated and tedious process for the user over a typical 12-day crystal growth cycle period, especially if there is a power failure where the vacuum/gas balance can be disrupted, etc.

With reference to FIG. 2, there is a prior art schematic illustration of a crystal growing process control system designated by reference numeral 200. The process control system 200 includes a process controller 50 and a temperature controller 52. The process controller 50 includes a timer 54, a memory 56, a comparator 58 for comparing the crystal diameter d with the predetermined diameter value stored in the memory 56, a monitor 60 for displaying the measured value of the melt level and outputting the measured melt level value to the comparator 58, an integrator 62 and a melt level sensor 64 for sensing the level of the melt in a crucible and controlling the feed of raw material to the melt.

The temperature controller 52 includes two input terminals 66. One input terminal 66a receives a temperature adjustment signal from a bottom heat thermocouple of the crystal-growing apparatus. The temperature adjustment signal indicates the melt temperature. Another input terminal 66b receives a correction signal generated by process controller 50 and is transmitted to the temperature controller 52 via the integrator 62. The function of the integrator 62 is to accumulate and store correction signals. The correction signal indicates how much should the melt temperature be adjusted. The timer 54 determines the time in the cycle between sampling, comparison and producing the correction signal.

The correction signal from integrator 62 and the temperature adjustment signal from
thermocouple are summed by the temperature controller 52 and the result is used to control the amount of heat generated by the bottom heater. The amount of heat generated by the bottom heater is increased or decreased according to the summation result. A look-up table or other data structure is accessed for correlating the summation result with the number of degrees that the heat generated by the bottom heater must be increased or decreased.

The temperature controller 52 also includes a bottom heater temperature controller 68 having manual switches 70a, 70b for manually “MAN” increasing/decreasing the amount of heat generated by the bottom heater. The temperature controller 52 further includes a display for displaying the measured process variable value (V.V.) and a display for displaying the set point value (S.P.).

This prior art set-up enables an automatic and manual control of the melt temperature or crystal-growth temperature, but it has some drawbacks.

First, the operator of this apparatus does not know if the temperature adjustment signal transmitted by the bottom heater thermocouple is causing the crystal-growth temperature to be changed, if the melt level sensor correction signal is causing the melt temperature to be changed, or if both signals are causing the melt temperature to be changed by the temperature controller 52. Second, in the event of a power failure, it would be difficult to restore the crystal-growth temperature. Therefore, it is an aspect of the invention to provide a crystal-growing apparatus which overcomes the drawbacks of the prior art.

### SUMMARY OF THE INVENTION

With the foregoing and other aspects in view there is provided, in accordance with the invention, a process control system for a crystal-growing apparatus which overcomes the drawbacks of the prior art. The process control system includes a process controller and a temperature controller. The process controller includes a comparator for comparing a crystal diameter d with a predetermined diameter value stored in a memory, a pulse generator and a melt level sensor for sensing the level of the melt in a crucible and controlling the feed of raw material to the melt.

The temperature controller includes an input terminal which receives a temperature adjustment signal from a bottom heat thermocouple indicating the melt temperature. Based on the melt temperature as indicated by the temperature adjustment signal, the temperature controller determines whether to increase, decrease or keep constant the melt temperature.

The temperature controller further includes two additional input terminals which receive pulses from the pulse generator for automatically controlling temperature switches of a bottom heater temperature controller in accordance with the sensed level of the melt in the crucible. The pulses are generated by the pulse generator upon receiving data from the comparator with respect to how much the temperature needs to be adjusted and in which direction (increase or decrease).

The comparator determines these parameters by taking the crystal diameter discrepancy value and accessing a look-up table or other data structure stored in the memory. The data structure preferably correlates the discrepancy value with the direction that the temperature must be adjusted and the amount the temperature needs to be adjusted.

Based on this inventive set-up, the pulse generator then generates pulses having a polarity which indicates whether the melt temperature is to be increased or decreased and also having a magnitude which indicates the amount of increase or decrease. The pulses are received by the two additional input terminals of the temperature controller and the switches are respectively triggered for a predetermined duration for increasing or decreasing the melt temperature. The switches can also be manually triggered by an operator for increasing/decreasing the melt temperature as in the prior art system described above with reference to FIG. 2.

Hence, according to the present invention, the temperature adjustment signal and the individual pulses generated by the process controller are independent of each other. Accordingly, an operator is able to know whether the bottom heater thermocouple or the process controller is adjusting the melt temperature during the crystal-growing process. Modern temperature controllers are protected against loss from AC power failure therefore immediately after power failure recovery, the operator would know the actual temperature and set point of the temperature controller and be able to restore crystal growth.

The invention further provides a method for controlling a melt temperature of a crystal-growing apparatus using a pulse generator. The method includes the steps of determining a crystal diameter of a crystal being grown by the crystal-growing apparatus; comparing the determined crystal diameter with a predetermined crystal diameter to determine a discrepancy value; correlating the discrepancy value with the following parameters: a direction that the melt temperature must be adjusted and an amount the melt temperature needs to be adjusted; transmitting the parameters to the pulse generator for using the parameters to generate pulses having a polarity which indicates whether the melt temperature is to be increased or decreased and also having a magnitude which indicates the amount of increase or decrease.

The method further includes the steps of transmitting the generated pulses to input terminals of a temperature controller of the crystal-growing apparatus for increasing or decreasing the melt temperature according to the polarity and magnitude of the pulses. The method controls the melt temperature independent of the melt temperature as determined by a bottom heater thermocouple of the crystal-growing apparatus. The method further includes the steps of determining a melt level of the crystal-growing apparatus; and using the determined melt level to determine the crystal diameter of the crystal being grown by the crystal-growing apparatus.

### BRIEF DESCRIPTION OF THE DRAWINGS

The invention will become more clearly understood from the following detailed description in connection with the accompanying drawings, in which:

FIG. 1 is a schematic illustration of a prior art crystal-growing apparatus;

FIG. 2 is a block diagram of a process control system having a process controller and temperature controller of a prior art crystal-growing apparatus; and

FIG. 3 is a block diagram of a process control system having a process controller and a temperature controller in accordance with the present invention.

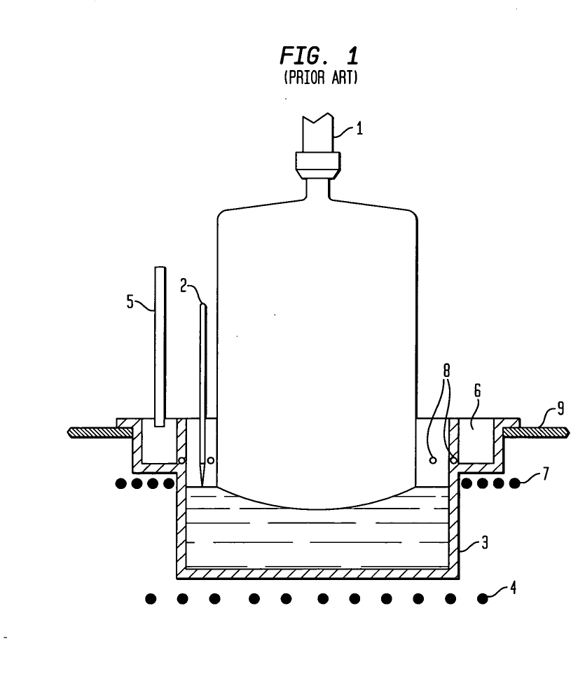

### DETAILED DESCRIPTION OF THE PREFERRED EMBODIMENTS

Referring now to FIG. 3, there is seen an exemplary embodiment of a process control system 300 for a crystal-growing apparatus in accordance with the present invention. The process control system includes a process controller 302 and a temperature controller 304.

The process controller 302 includes a timer 306, a memory 308, a comparator 310 for comparing a crystal diameter d with a predetermined diameter value stored in the memory 308, a monitor 312, a pulse generator 314 and a melt level sensor 316 for sensing the level of the melt in a crucible and controlling the feed of raw material to the melt. The function of the timer 306 and the monitor 312 is the same as the function of the timer 54 and monitor 60, respectively.

The temperature controller 304 includes an input terminal 318 and associated circuitry 319 which receive a temperature adjustment signal from a bottom heater thermocouple of the crystal-growing apparatus which indicates the melt temperature. Based on the melt temperature as indicated by the temperature adjustment signal, the circuitry 319 of the temperature controller 304 determines whether to increase, decrease or keep constant the melt temperature.

The temperature controller 304 further includes a display for displaying the measured process variable value (V.V.) and a display for displaying the set point value (S.P.). The temperature controller 304 also includes two additional input terminals 320a, 320b which receive pulses from the pulse generator 314 for automatically controlling temperature switches 322a, 322b of a bottom heater temperature controller 324 in accordance with the sensed level of the melt in the crucible.

The pulses are generated by the pulse generator 314 upon receiving data from the comparator 310 with respect to how much the temperature needs to be adjusted and in which direction (increase or decrease). If the temperature needs to be increased, the pulses control switch 322a, and if the temperature needs to be decreased, the pulses control switch 322b.

The comparator 310 determines these parameters by taking the crystal diameter discrepancy value and accessing a look-up table or other data structure stored in the memory 308. The data structure preferably correlates the discrepancy value with the direction that the melt temperature must be adjusted and the amount the melt temperature needs to be adjusted.

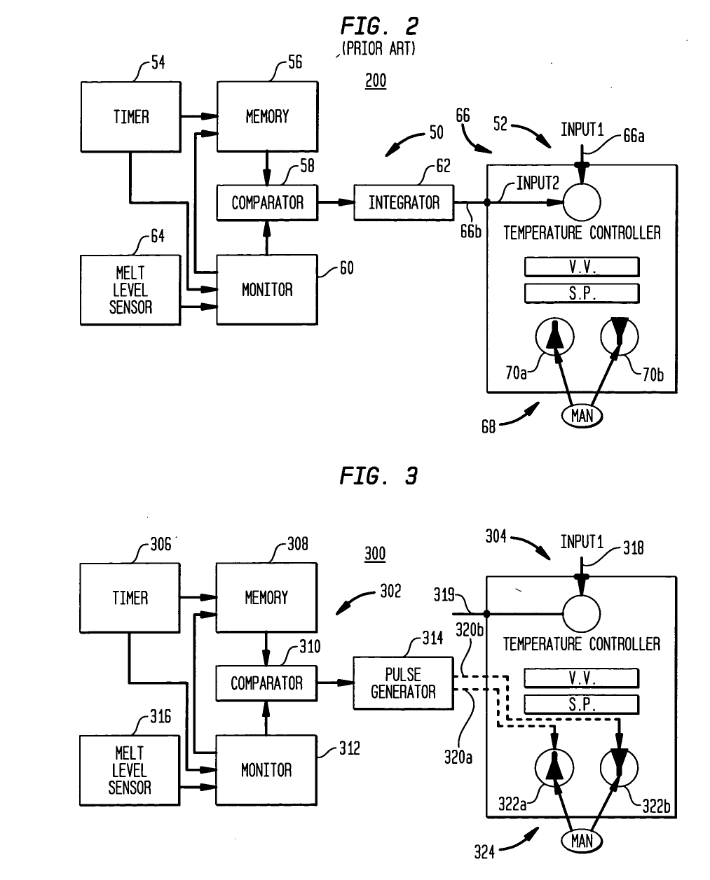

Based on this inventive set-up, the pulse generator 314 then generates pulses having a polarity which indicates whether the melt temperature is to be increased or decreased and also having a magnitude which indicates the amount of increase or decrease. The pulses are received by input terminals 320a, 320b of the temperature controller 304 and switches 322a, 322b are respectively triggered for a predetermined duration for increasing or decreasing the melt temperature. The switches 322a, 322b can also be manually triggered “MAN” by an operator for increasing/decreasing the melt temperature as in the prior art system described above with reference to FIG. 2.

Hence, according to the present invention, the temperature adjustment signal and the individual pulses generated by the process controller 302 are independent of each other. Accordingly, an operator is able to know whether the bottom heater thermocouple or the process controller 302 is adjusting the melt temperature during the crystal-growing process. Modern temperature controllers are protected against loss from AC power failure therefore immediately after power failure recovery, the operator would know the actual temperature set points of the temperature controller 304 and be able to restore crystal growth.

Additionally, according to the present invention, the operator has greater knowledge of the process parameters as received by the pulse generator 314, thereby increasing the confidence of the operator in operating the process control system 300. Further, the temperature controller 304 is operated in exactly the same way that the operator would operate it.

The invention further provides a method for controlling a melt temperature of a crystal-growing apparatus using a pulse generator. The method includes the steps of determining a crystal diameter of a crystal being grown by the crystal-growing apparatus; comparing the determined crystal diameter with a predetermined crystal diameter to determine a discrepancy value; correlating the discrepancy value with the following parameters: a direction that the melt temperature must be adjusted and an amount the melt temperature needs to be adjusted; transmitting the parameters to the pulse generator for using the parameters to generate pulses having a polarity which indicates whether the melt temperature is to be increased or decreased and also having a magnitude which indicates the amount of increase or decrease.

The method further includes the steps of transmitting the generated pulses to input terminals of a temperature controller of the crystal-growing apparatus for increasing or decreasing the melt temperature according to the polarity and magnitude of the pulses. The method controls the melt temperature independent of the melt temperature as determined by a bottom heater thermocouple of the crystal-growing apparatus. The method further includes the steps of determining a melt level of the crystal-growing apparatus; and using the determined melt level to determine the crystal diameter of the crystal being grown by the crystal-growing apparatus.

The described embodiments of the present invention are intended to be illustrative rather than restrictive, and are not intended to represent every embodiment of the present invention. Various modifications and variations can be made without departing from the spirit or scope of the invention as set forth in the following claims both literally and in equivalents recognized in law.

1. A method for controlling a melt temperature of a crystal-growing apparatus comprising the steps of:
determining a crystal diameter of a crystal being grown by the crystal-growing apparatus;
comparing the determined crystal diameter with a predetermined crystal diameter to determine a discrepancy value;
correlating the discrepancy value with the following parameters: a direction that the melt temperature must be adjusted and an amount the melt temperature needs to be adjusted;
transmitting the parameters to a pulse generator for using the parameters to generate pulses having a polarity which indicates whether the melt temperature is to be increased or decreased and also having a magnitude which indicates the amount of increase or decrease; and
transmitting the generated pulses to at least one input terminal of a temperature controller for increasing or decreasing the melt temperature of the crystal-growing apparatus according to the polarity and magnitude of the pulses.

2. The method according to claim 1, wherein the method controls the melt temperature independently of the melt temperature as determined by a bottom heater of the crystal-growing apparatus.

3. The method according to claim 1, further comprising the steps of:
determining a melt level of the crystal-growing apparatus; and
using the determined melt level to determine the crystal diameter of the crystal being grown by the crystal-growing apparatus.

4. The method according to claim 1, further comprising the steps of:
receiving a temperature adjustment signal from a bottom heater thermocouple of the crystal-growing apparatus which indicates the melt temperature; and
determining whether to increase, decrease or keep constant the melt temperature based on the melt temperature as indicated by the temperature adjustment signal.

5. The method according to claim 1, further comprising the step of manually increasing/decreasing the melt temperature.

6. The method according to claim 1, wherein the step of correlating the discrepancy value includes the step of accessing a data structure stored in a memory.

7. A system for controlling a melt temperature of a crystal-growing apparatus, said system comprising:
means for determining a crystal diameter of a crystal being grown by the crystal-growing apparatus;
means for comparing the determined crystal diameter with a predetermined crystal diameter to determine a discrepancy value;
means for correlating the discrepancy value with the following parameters: a direction that the melt temperature must be adjusted and an amount the melt temperature needs to be adjusted;
means for transmitting the parameters to a pulse generator for using the parameters to generate pulses having a polarity which indicates whether the melt temperature is to be increased or decreased and also having a magnitude which indicates the amount of increase or decrease; and
means for transmitting the generated pulses to at least one input terminal of a temperature controller for increasing or decreasing the melt temperature of the crystal-growing apparatus according to the polarity and magnitude of the pulses.

8. The system according to claim 7, wherein the apparatus controls the melt temperature independently of the melt temperature as determined by a bottom heater of the crystal-growing apparatus.

9. The system according to claim 7, further comprising means for determining a melt level of the crystal-growing apparatus for use by the means for determining the crystal diameter of the crystal being grown by the crystal-growing apparatus.

10. The system according to claim 7, further comprising:
means for receiving a temperature adjustment signal from a bottom heater thermocouple of the crystal-growing apparatus which indicates the melt temperature; and
means for determining whether to increase, decrease or keep constant the melt temperature based on the melt temperature as indicated by the temperature adjustment signal.

11. The system according to claim 7, further comprising means for manually increasing/decreasing the melt temperature.

12. The system according to claim 7, wherein the means for correlating the discrepancy value includes means for accessing a data structure stored in a memory.

13. A process control system for controlling a melt temperature of a crystal-growing apparatus, said process control system comprising:
circuitry for determining a crystal diameter of a crystal being grown by the crystal-growing apparatus, for comparing the determined crystal diameter with a predetermined crystal diameter to determine a discrepancy value, and for correlating the discrepancy value with the following parameters: a direction that the melt temperature must be adjusted and an amount the melt temperature needs to be adjusted;
a pulse generator for receiving the parameters and for generating pulses having a polarity which indicates whether the melt temperature is to be increased or decreased and also having a magnitude which indicates the amount of increase or decrease; and
a temperature controller having at least one input terminal for receiving the generated pulses and for increasing or decreasing the melt temperature of the crystal-growing apparatus according to the polarity and magnitude of the pulses.

14. The process control system according to claim 13, wherein the process control system controls the melt temperature independently of the melt temperature as determined by a bottom heater of the crystal-growing apparatus.

15. The process control system according to claim 13, wherein the circuitry further determines a melt level of the crystal-growing apparatus for use in determining the crystal diameter of the crystal being grown by the crystal-growing apparatus.

16. The process control system according to claim 13, wherein the temperature controller further comprises:
an input terminal for receiving a temperature adjustment signal from a bottom heater thermocouple of the crystal-growing apparatus which indicates the melt temperature; and
circuitry for determining whether to increase, decrease or keep constant the melt temperature based on the melt temperature as indicated by the temperature adjustment signal.

17. The process control system according to claim 13, wherein the temperature controller further comprises at least one manually-operational switch for manually increasing/decreasing the melt temperature.

18. The process control system according to claim 13, wherein the circuitry further accesses a data structure stored in a memory for correlating the discrepancy value.

19. A process control system for controlling a melt temperature of a crystal-growing apparatus, said process control system comprising:
a pulse generator for generating pulses having a polarity which indicates whether the melt temperature is to be increased or decreased and also having a magnitude which indicates the amount of increase or decrease; and
a temperature controller having at least one input terminal for receiving the generated pulses and for increasing or decreasing the melt temperature of the crystal-growing apparatus according to the polarity and magnitude of the pulses.

20. The process control system according to claim 19, wherein the process control system controls the melt temperature independently of the melt temperature as determined by a bottom heater of the crystal-growing apparatus.
